(19) United States
(12) Patent Application Publication
(10) Pub. No.: US 2009/0117495 A1
(43) Pub. Date: May 7, 2009

(54) METHOD FOR FORMING A PATTERN IN A SEMICONDUCTOR DEVICE AND METHOD FOR MANUFACTURING A FLASH MEMORY DEVICE

(75) Inventor: Joo Hong Jeong, Seoul (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-Si (KR)

(21) Appl. No.: 12/119,926

(22) Filed: May 13, 2008

(30) Foreign Application Priority Data
Nov. 1, 2007 (KR) 10-2007-0111097

(51) Int. Cl. G03F 7/26

(52) U.S. Cl. 430/323

(57) ABSTRACT

A pattern formation method of a semiconductor device, and to a manufacturing method of a flash memory, in which spacer patterning technology is performed while two hard mask layers having a different etching characteristics are used, such that the patterning can be performed by using only a spacer as a mask in the region which requires a small pattern. Additionally, the patterning can be performed by using a hard mask layer pattern and the spacer as a mask in a region which requires a large pattern. Therefore, the pattern formation method of the invention can be used to form a semiconductor device with patterns having various sizes using just a single patterning.

### CROSS-REFERENCE TO RELATED APPLICATION

The priority of Korean patent application number 10-2007-0111097, filed on Nov. 1, 2007, the disclosure of which is incorporated by reference in its entirety, is claimed.

### BACKGROUND OF THE INVENTION

The invention relates to a method for forming a pattern of a semiconductor device and, more particularly, to a pattern formation method of capable of forming a pattern having various sizes in a semiconductor device, by performing a spacer patterning technique while using two hard mask layers preferably having different etching characteristics.

Pattern sizes have been reduced with the trend toward high integration of semiconductor devices. Accordingly, various approaches are made in order to form a fine pattern in the apparatus and process side.

For example, methods of reducing the exposure wavelength, or enlarging the size of a lens have been mainly used for fine pattern formation.

However, such methods require the development of an apparatus, so that the cost of capital investment increases, and have had difficulty in operating the apparatus, thereby resulting in the occurrence of many problems.

Hence, double exposure technology or the SPT (Spacer Patterning Technology) method has been suggested as an alternative method for forming a fine pattern complying with the high integration while using existing apparatus.

FIGS. 1a to 1f are cross-sectional views illustrating a pattern formation method of a semiconductor device according to the prior art, while using spacer patterning technology.

Referring to FIG. 1a, an underlying layer 12, a first hard mask layer 14, a second hard mask layer 16, and a photoresist layer (not shown) are sequentially formed over a semiconductor substrate 10. The photoresist layer (not shown) is exposed and developed to form a photoresist pattern 18.

Here, the second hard mask layer 16 illustratively comprises a trilaminar structure.

Referring to FIG. 1b, the second hard mask layer 16 having a trilaminar structure is successively etched with the photoresist pattern 18 as a mask to form the second hard mask pattern 16a.

Referring to FIG. 1c, the photoresist pattern 18 and two upper layers of the second hard mask pattern 16a are eliminated (i.e., removed) by an etch process which has a same selectivity with respect to each of the layers.

The polysilicon layer (not shown) is formed over the entire structure of the first hard mask layer 14 including the lowest layer of the second hard mask pattern 16b remaining in a first floor of the structure.

A spacer 22 is formed on side walls of the second hard mask pattern 16b by etching back the polysilicon layer (not shown).

Referring to FIG. 1d, the second hard mask pattern 16b between the spacers 22 is eliminated. At this time, it is preferable that the second hard mask pattern 16b is eliminated with a method having a different selectivity for the second hard mask pattern 16b than for the spacer 22.

Referring to FIG. 1e, a first hard mask pattern 14a is formed by etching the first hard mask layer 14 using the spacer 22 as a mask.

Referring to FIG. 1f, an underlying layer pattern 12a is formed by etching the underlying layer 12 using the first hard mask pattern 14a and the spacer 22 as a mask.

There is a problem that only the pattern having a size corresponding to the critical dimension (CD) of the spacer 22 is formed when using the spacer patterning technology according to the prior art. However, in a real design, various sizes of patterns are required. Therefore, according to the prior art, since only the pattern of the CD identical with the CD of spacer is formed, an additional patterning process has to be more performed in order to form various sizes of patterns.

### BRIEF SUMMARY OF THE INVENTION

According to an embodiment of the invention, a method for forming the pattern in the semiconductor device comprises: sequentially forming an underlying layer, a first hard mask layer, and a second hard mask pattern over a semiconductor substrate; forming a photoresist pattern adjacent to the second hard mask pattern on the first hard mask layer; etching the first hard mask layer using the second hard mask pattern and the photoresist pattern as a mask; removing the photoresist pattern to form an exposed first hard mask pattern and a stacking pattern formed of a second hard mask pattern overlaying a first hard mask pattern, the stacking pattern and the exposed first hard mask pattern each defining side walls; forming spacers on side walls of the stacking pattern and the exposed first hard mask pattern; removing the exposed first hard mask pattern; and etching the underlying layer using the stacking pattern and spacers as a mask to form first and second underlying layer patterns.

According to another embodiment of the invention, a method for manufacturing flash memory device comprises: sequentially forming an underlying layer and a first hard mask layer over a semiconductor substrate; forming a second hard mask pattern on the region of a gate line for a source select line (SSL) on the first hard mask layer; forming a photoresist pattern on the region of a word line adjacent to the second hard mask pattern on the first hard mask layer; etching the first hard mask layer using the second hard mask pattern and the photoresist pattern as a mask; removing the photoresist pattern to form an exposed first hard mask pattern and a stacking pattern formed of the second hard mark pattern overlying the first hard mask pattern, the stacking pattern and the exposed first hard mask pattern each defining side walls; forming spacers on the side walls of the stacking pattern and the exposed first hard mask pattern; removing the exposed first hard mask pattern; and etching the underlying layer using the stacking pattern and the spacers as a mask to form first and second underlying layer patterns.

### BRIEF DESCRIPTION OF THE DRAWINGS

FIGS. 1a to 1f are cross-sectional views illustrating the pattern formation method of a semiconductor device according to the prior art.

FIGS. 2a to 2f are cross-sectional views illustrating the pattern formation method of a semiconductor device according to the invention.

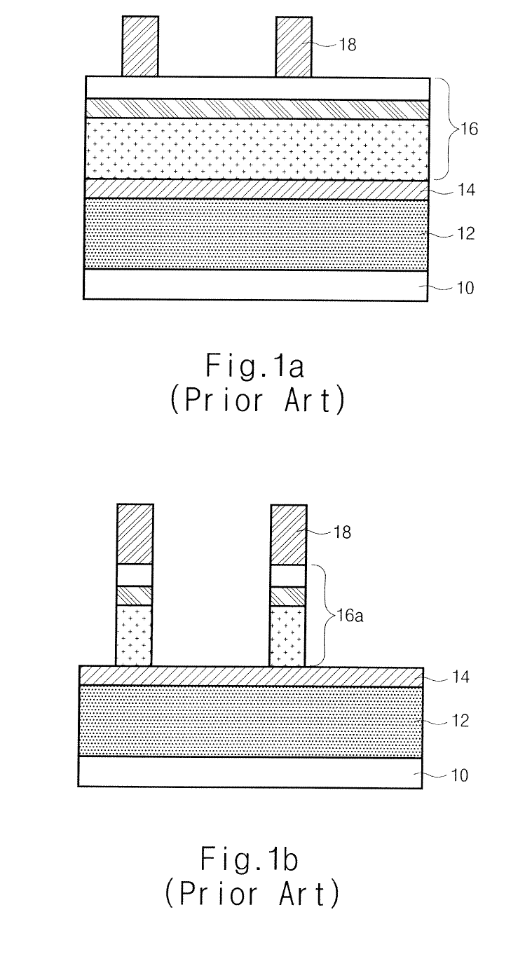

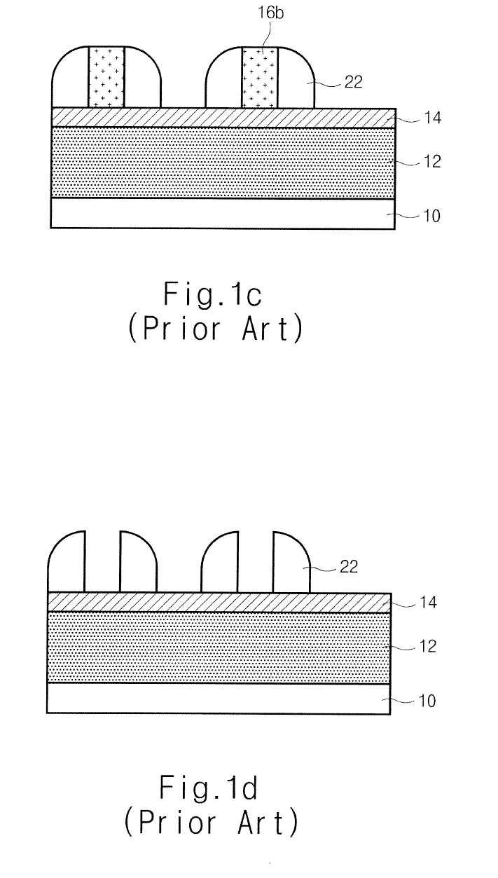

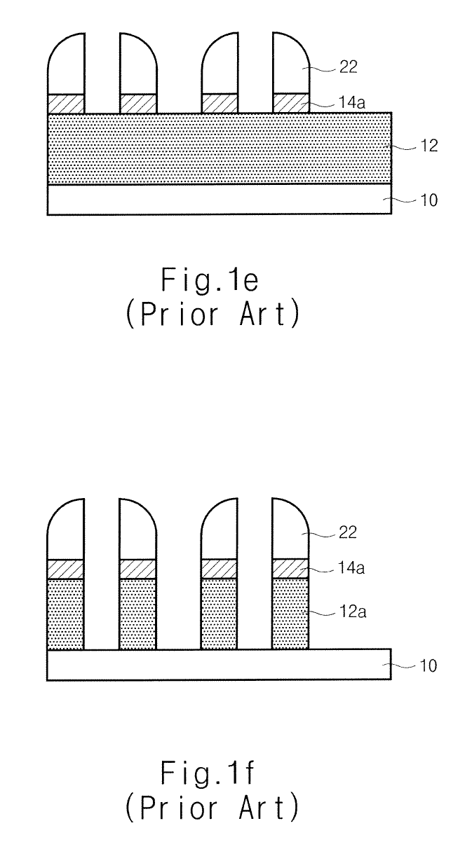

### DESCRIPTION OF EMBODIMENTS

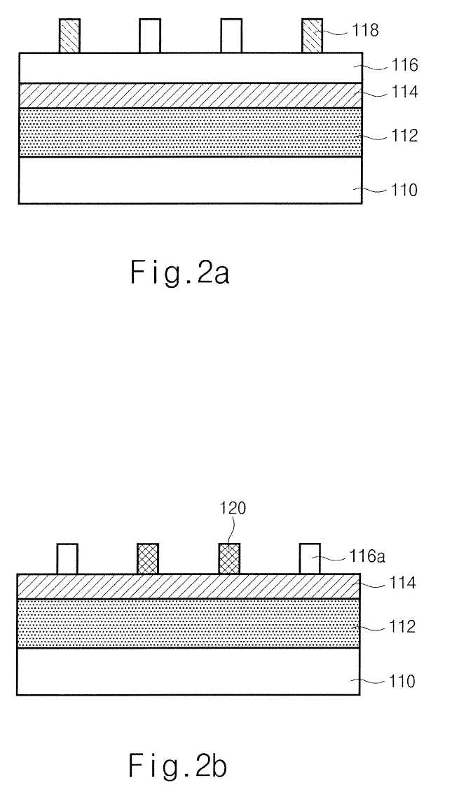

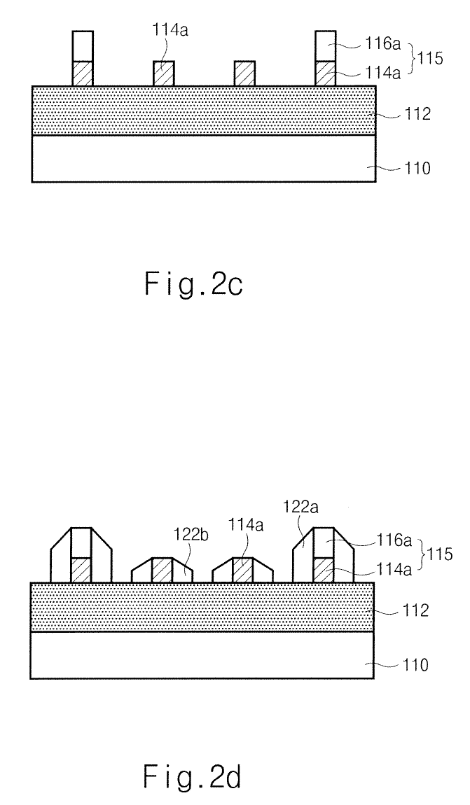

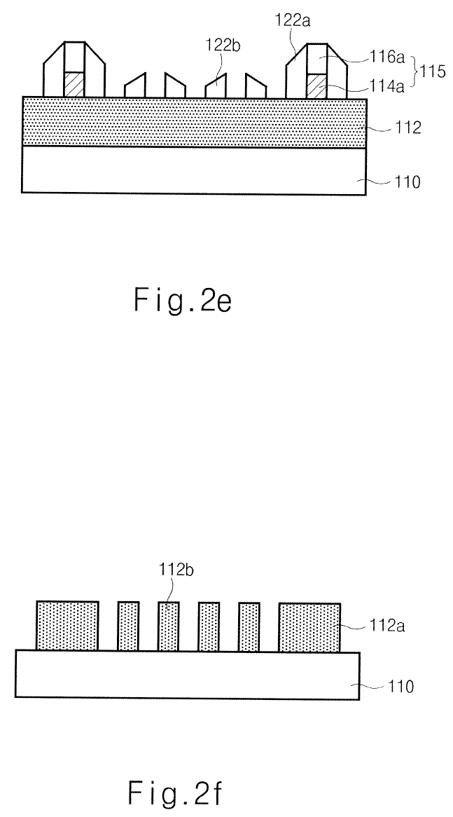

FIGS. 2a to 2f are cross-sectional views illustrating the pattern formation method of a semiconductor device according to the invention.

Referring to FIG. 2a, an underlying layer 112, a first hard mask layer 114, and a second hard mask layer 116 are successively formed over a semiconductor substrate 110.

The underlying layer 112 preferably has a thickness of 1000 Å to 2000 Å and preferably comprises a plasma-enhanced tetraethyl orthosilicate (PE-TEOS) film. The first hard mask layer 114 preferably has a thickness of 1000 Å to 2000 Å and preferably comprises a polysilicon layer. In addition, the second hard mask layer 116 preferably has a thickness of 2000 Å to 4000 Å and preferably comprises an oxide film.

After the first photoresist (not shown) is formed over the second hard mask layer 116, the first photoresist (not shown) is exposed and developed to form a first photoresist pattern 118 at the gate line region for a source select line (SSL).

Referring to FIG. 2b, a second hard mask pattern 116a is formed by etching the second hard mask layer 116 using the first photoresist pattern 118 as a mask.

Then, the first photoresist pattern 118 is removed.

A second photoresist layer (not shown) is formed over the first hard mask layer 114 including the second hard mask pattern 116a.

The second photoresist layer (not shown) is exposed and developed to form a second photoresist pattern 120 adjacent to (i.e., on one side or both sides of) the second hard mask pattern 116a on the first hard mask layer 114.

Here, the second photoresist pattern 120 is illustratively formed on the word line region. The CD of the second photoresist pattern 120 is formed identically with the CD of the second hard mask pattern 116a.

Referring to FIG. 2c, the first hard mask layer 114 is etched using the second hard mask pattern 116a and the second photoresist pattern 120 as a mask to form a first hard mask pattern 114a. Then, the second photoresist pattern 120 is removed.

Consequently, in the both sides of the edge part of the upper portion of the underlying layer 112, a stacking pattern 115 of the first hard mask pattern 114a underlying the second hard mask pattern 116a is formed. The first hard mask pattern 114a is formed between the stacking pattern 115 adjacent to the stacking pattern 115.

Referring to FIG. 2d, a film for spacer preferably having a thickness of 1000 Å to 5000 Å is deposited, on the stacking pattern 115 of the first hard mask pattern 114a and the second hard mask pattern 116a, and throughout the upper portion of the underlying layer 112 including the first hard mask pattern 114a.

Here, the film for spacer preferably comprises a nitride film.

A first spacer 122a is formed on side walls of the stacking pattern 115 of the first hard mask pattern 114a and the second hard mask pattern 116a, while a second spacer 122b is formed on the side walls of the first hard mask layer pattern 114a side walls, by etching back the film for spacer.

Referring to FIG. 2e, the first hard mask pattern 114a is removed, preferably by etching using an etchant gas selected from fluorocarbon, oxygen and combinations thereof. The first hard mask pattern 114a and the second spacer 122b have an etching selectivity difference. The first hard mask pattern 114a is only removed because the first hard mask pattern 114a has an etching speed faster than that of the second spacer 122b. At this time, as to the stacking pattern 115 of the first hard mask pattern 114a and the second hard mask pattern 116a, the second hard mask pattern 116a plays a role of barrier, therefore, the first hard mask pattern 114a is not removed by etching.

As a result, in the both sides of the edge part of the upper portion of the underlying layer 112, the stacking pattern 115 in which the first spacer 122a is formed exists. The second spacer 122b smaller than the first spacer exists between the stacking pattern 115 in which the first spacer 122a is formed.

Referring to FIG. 2f, a first underlying layer pattern 112a is formed by etching the underlying layer 112 using the stacking pattern 115 in which the first spacer 122a is formed as a mask.

In addition, a second underlying layer pattern 112b which has a CD smaller than the CD of the first underlying layer pattern 112a is formed by etching the underlying layer 112 using only the second spacer 122b as a mask.

As described in the above, in the invention, while the first hard mask layer pattern 114a is eliminated in order to use only the second spacer 122b as a mask in case of the region which requires a small pattern, the second hard mask layer pattern 116a is not etched with the means by which the first hard mask layer pattern 114a is etched in case of the region which requires a large pattern, but plays a role of barrier, thereby preventing the first hard mask layer pattern 114a of the lower portion from being eliminated.

In short, in the invention, while the first hard mask layer 114 and the second hard mask layer 116 which have different etching characteristics are used, the spacer patterning technology is performed. Thus, by using only the second spacer 122b as a mask, the patterning can be performed in case of the region which requires a small pattern.

In case of the region which requires a large pattern, the patterning is performed by using the stacking pattern 115 of the first hard mask layer 114 and the second hard mask layer 116 using the first spacer 122a as a mask. In that way, the pattern having two kinds of sizes can be formed with a single patterning.

Additionally, in the invention, by using two or more hard mask layers having a different etching characteristics, it is possible to form a pattern having various sizes.

The pattern formation method of semiconductor device can be applied to not only DRAM but also to SRAM, to flash memory, and to logic devices, for example.

In the invention, while two hard mask layers having a different etching characteristics are used, spacer patterning technology is performed. Accordingly, the pattern having two kinds of sizes can be formed with just a single patterning, thereby, satisfying the design rule.

In addition, in the invention, it is possible to form a pattern having various sizes in case of using two or more hard masks.

The foregoing embodiments of the invention are illustrative and not limiting. Various alternatives and equivalents are possible. The invention is not limited by the type of deposition, etching polishing, and patterning steps described herein, nor is the invention limited to any specific type of semiconductor device. For example, the invention may be implemented in a dynamic random access memory DRAM device or non volatile memory device. Other additions, subtractions, or modifications are intended to fall within the scope of the appended claims.

What is claimed is:

1. A method for forming a pattern in a semiconductor device comprising:
sequentially forming an underlying layer, a first hard mask layer, and a second hard mask pattern over a semiconductor substrate;
forming a photoresist pattern adjacent to the second hard mask pattern on the first hard mask layer;
etching the first hard mask layer using the second hard mask pattern and the photoresist pattern as a mask;
removing the photoresist pattern to form an exposed first hard mask pattern and a stacking pattern formed of a second hard mask pattern overlaying a first hard mask pattern, the stacking pattern and the exposed first hard mask pattern each defining side walls;
forming spacers on side walls of the stacking pattern and the exposed first hard mask pattern;
removing the exposed first hard mask pattern; and
etching the underlying layer using the stacking pattern and spacers as a mask to form first and second underlying layer patterns.

2. The method according to claim 1, wherein the first hard mask layer comprises a polysilicon layer.

3. The method according to claim 1, wherein the second hard mask pattern comprises an oxide layer.

4. The method according to claim 1, wherein the spacer comprises a nitride layer.

5. The method according to claim 1, wherein the first hard mask layer has a thickness ranging from about 1000 Å to about 2000 Å.

6. The method according to claim 1, wherein the second hard mask pattern has a thickness ranging from about 2000 Å to about 4000 Å.

7. The method according to claim 1, wherein the spacers have a thickness ranging from about 1000 Å to about 5000 Å.

8. The method according to claim 1, wherein removing the exposed first hard mask pattern comprises etching with an etching gas selected from the group consisting of carbon fluoride, oxygen, and combinations thereof.

9. The method according to claim 1, wherein the first hard mask pattern has an etch selectivity different from the etch selectivity of the spacer and the second hard mask pattern.

10. The method according to claim 1, wherein a critical dimension (CD) of the first underlying layer pattern is larger than a CD of the second underlying layer pattern.

11. The method according to claim 1, wherein forming a photoresist pattern comprises using a light source having a wavelength selected from the group consisting i-ray light sources of 365 nm, KrF light sources of 248 nm, ArF light sources of 193 nm, F2 light sources of 157 nm, and extreme ultraviolet (EUV) light sources of 13 nm.

12. A method for manufacturing flash memory device, comprising:
sequentially forming an underlying layer and a first hard mask layer over a semiconductor substrate;
forming a second hard mask pattern on the region of a gate line for a source select line (SSL) on the first hard mask layer;
forming a photoresist pattern on the region of a word line adjacent to the second hard mask pattern on the first hard mask layer;
etching the first hard mask layer using the second hard mask pattern and the photoresist pattern as a mask;
removing the photoresist pattern to form an exposed first hard mask pattern and a stacking pattern formed of the second hard mark pattern overlying the first hard mask pattern, the stacking pattern and the exposed first hard mask pattern each defining side walls;
forming spacers on the side walls of the stacking pattern and the exposed first hard mask pattern;
removing the exposed first hard mask pattern; and
etching the underlying layer using the stacking pattern and the spacers as a mask to form first and second underlying layer patterns.

13. The method according to claim 12, wherein the first hard mask layer comprises a polysilicon layer.

14. The method according to claim 12, wherein the second hard mask pattern comprises an oxide layer.

15. The method according to claim 12, wherein the spacer comprises a nitride layer.

16. The method according to claim 12, wherein the first hard mask layer has a thickness ranging from about 1000 Å to about 2000 Å.

17. The method according to claim 12, wherein the second hard mask pattern has a thickness ranging from about 2000 Å to about 4000 Å.

18. The method according to claim 12, wherein the spacers have a thickness ranging from about 1000 Å to about 5000 Å.

19. The method according to claim 12, wherein removing the exposed first hard mask pattern comprises etching with an etching gas selected from the group consisting of carbon fluoride, oxygen, and combinations thereof.

20. The method according to claim 12, the first hard mask pattern has an etch selectivity different from the etch selectivity of the spacer and the second hard mask pattern.

21. The method according to claim 12, wherein a critical dimension (CD) of the first underlying layer pattern is larger than a CD of the second underlying layer pattern.

22. The method according to claim 12, wherein forming a photoresist pattern comprises a light source of a wavelength selected from a group consisting of i-ray light sources of 365 nm, KrF light sources of 248 nm, ArF light sources of 193 nm, F2 light sources of 157 nm, and extreme ultraviolet (EUV) light sources of 13 nm.
